(19) United States
(12) Patent Application Publication
(10) Pub. No.: US 2011/0080928 A1
(43) Pub. Date: Apr. 7, 2011

(54) LASER DEVICE

(75) Inventors: Noriyuki YOSHIKAWA, Osaka (JP); Yasutake YAGUCHI, Osaka (JP)

(73) Assignee: PANASONIC CORPORATION, Osaka (JP)

(21) Appl. No.: 12/887,932

(22) Filed: Sep. 22, 2010

(30) Foreign Application Priority Data
Oct. 1, 2009 (JP) 2009-230008

(51) Int. Cl. H01S 5/02

(52) U.S. Cl. 372/43.01

(57) ABSTRACT

To provide a laser device having high strength against mechanical stress. The laser device includes: a laser element; a plate-like lead frame including through-holes, and on whose front plane the laser element is mounted; lead terminals; trenches provided between an end of the lead frame in a laser emission direction of the laser element and the through-holes; and a resin dam formed on the front plane of the lead frame using a molding resin to protrude in an area surrounding the laser element including positions of the through-holes, and having an open part in the laser emission direction. The molding resin further fills the through-holes and the trenches, and bonds the lead frame and the resin dam by sealing together a part of each of the lead terminals and a part of the front plane and the back plane of the lead frame, in a vicinity of the lead terminals.

### BACKGROUND OF THE INVENTION

(1) Field of the Invention

The present invention relates to a semiconductor laser device used in writing, erasing, and reading of information to and from an optical disc such as a DVD.

(2) Description of the Related Art

Conventional examples are described below.

A laser device which uses a lead frame onto which a laser element is mounted and a resin dam is formed in the three directions other than a laser emission direction is described in Unexamined Japanese Patent Application Publication No. 2002-43678 and Unexamined Japanese Patent Application Publication No. 2005-116699 (FIG. 1) (Patent References 1 and 2, respectively).

Patent Reference 1 has the technical problems of the strength of the lead frame and the flatness of the bottom plane of the lead frame, and describes providing bumps on the back plane of the lead frame to alter the thickness of the lead frame.

Furthermore, Patent Reference 2 discloses: a through-hole which is filled with resin for improving adhesion between the lead frame and the resin; and the resin which continuously covers the front and back planes of the lead frame around the end of the lead frame in the laser emission direction.

### SUMMARY OF THE INVENTION

FIG. 5 shows a perspective view (a cut-out view showing the internal structure) of a conventional laser device. In a laser device 100 using a lead frame 111, the mechanical strength of open-end parts 113a and 113b of a resin dam 113 which is single-plane sealed is not dependent on the adhesion of the molding resin 112 to the lead frame 111 but is dependent on the strength produced by the structure thereof. This is because the strength of adhesion between the molding resin 112 and the lead frame 111 is intrinsically weak. In FIG. 5, the plane of the lead frame 111 on which the resin dam 113 is formed is the plane on which a laser element is to be mounted. When the laser emission direction is the upward direction as seen from the laser mounting plane, lead terminals 116 are placed in the downward direction, and the resin dam 113 formed on the lead frame 111 is open in the upward direction (the laser emission direction). The width of the open-end parts 113a and 113b of the resin dam 113 near the open end shown in FIG. 5, is narrow in order to allow miniaturization of the laser device 100. The mechanical strength of the open-end parts 113a and 113b of the resin dam 113 in the case where a pinching load is applied by tweezers and the like from the lateral direction, as shown by the arrows in FIG. 5, is weak. As such, in the single-plane sealed state, there are instances when the open-end parts 113a and 113b of the resin dam 113 deform under mechanical stress, resulting in a defective piece.

Furthermore, since the laser device is an extremely small component, handling is difficult and there are cases where, for example, load is applied to the open-end parts 113a and 113b of the resin dam 113 when the laser device is pinched for lifting using tweezers during the manufacturing process, thereby leading to deformation and the emergence of defective pieces, and thus reducing yield.

Although packages such as a Quad Flat Package (QFP) or Ball Grid Array (BGA) allow picking-up by suctioning on the front plane using vacuum tweezers, the laser device 100 which is the subject of the present invention is merely an open package in which, basically, the periphery of the laser element is surrounded by the resin dam 113, and thus suctioning by vacuum tweezers is not possible.

In this manner, since the laser device 100 requires handling with tweezers which grasp by mechanical pinching, it is necessary to have a design which focuses attention on mechanical stress.

On the other hand, although mechanical strength can be improved with a design which wraps the molding resin 112 around the front and back in the upward direction of the lead frame 111, there is the problem of resin burr as described below. In order to keep the contour precision of the laser device 100 high, the contour of the lead frame 111 is formed using a mold press capable of forming the contour with high precision, and part of the shape of the lead frame 111 are adopted as a reference planes for the size of the laser device 100. When resin burr appears on parts of an X-reference plane 114 and a Y-reference plane 115, the resin burr becomes wedged between the laser device 100 and the product on which the laser device 100 is to be mounted, and thus precise alignment cannot be achieved. Furthermore, when resin burr is generated, there are instances where, during the manufacturing process, particularly during the mounting of the laser element, resin burr that has come off may settle on a laser element mounting part 111a thereby causing defective laser element mounting, or wedge itself between a wire and the laser element thereby causing defective electrical conduction.

As such, in the open-end parts 113a and 113b of the resin dam 113 which are located higher in the upward direction than through-holes 117, it is necessary to adopt single-plane sealing in which the molding resin does not wrap around the front and back of the lead frame 111, and it is necessary to improve mechanical strength given such a situation.

The present invention is conceived in view of the above-described problem and has as an object to provide a laser device having high strength against mechanical stress.

In order to solve the above-described problem, the laser device according to an aspect of the present invention includes: a laser element; a plate-like lead frame which includes through-holes that penetrate a front plane and a back plane of the lead frame, the front plane being a surface on which the laser element is mounted such that an emission direction of a laser of the laser element is approximately parallel to the front plane; lead terminals provided at an end of the lead frame in a direction opposite to the emission direction; trenches provided on the front plane of the lead frame between an end of the lead frame in the emission direction and the through-holes; and a resin dam formed on the front plane of the lead frame using a resin so as to protrude in an area surrounding the laser element including positions of the through-holes, the resin dam having an open part in the emission direction, wherein the resin further fills the through-holes and the trenches, and bonds the lead frame and the resin dam by sealing together a part of each of the lead terminals and a part of the front plane and the back plane of the lead frame, in a vicinity of the lead terminals.

According to this configuration, having trenches in the lead frame allows the resin which forms the resin dam to fill the trenches, thereby improving the mechanical strength between the lead frame and the resin dam near the end of the lead frame in the emission direction of the laser.

Furthermore, each of the trenches may have a shape that is elongated in a direction approximately parallel to the emission direction.

Furthermore, each of the trenches may be formed with a width that increases towards the end of the lead frame in the emission direction.

Furthermore, each of the trenches may be formed with a depth that increases towards the end of the lead frame in the emission direction.

According to this configuration, it is possible to facilitate the flowing of the resin into the trenches, eliminate resin voids, and reduce the risk of mechanical strength deterioration.

Here, in each of the trenches, a first wall closer to a mounting position of the laser element may have an approximately-vertical precipitous slope, and a second wall farther from the mounting position of the laser element may have a gentler slope than the first wall.

According to this configuration, at the time of pressing for forming the lead frame, it is possible to prevent the displaced material of the lead frame (for example, the metal material of the lead frame that is displaced in a press process for forming the trenches using the mold tool) from moving toward the laser element mounting plane-side, and thus the flatness of the laser element mounting part on the front plane of the lead frame, onto which the laser element is to be mounted, is not impaired, heat conduction characteristics are not impaired, and misalignment of the emission direction of the laser can be suppressed.

Furthermore, the trenches may be formed axisymmetrically with the emission direction as an axis of symmetry.

According to this configuration, it is possible to maintain the size precision of the lead frame, and it is possible to prevent deviations in the size of the end of the lead frame in the emission direction of the laser.

Here, a depth of the trenches may be 15 μm or more and may be equal to or less than half a thickness of the lead frame.

According to this configuration, it is possible to improve the mechanical strength between the lead frame and the resin dam near the end of the lead frame in the emission direction of the laser.

Here, in the front plane of the lead frame, a shortest distance between the through-holes and an end plane of the resin dam near the end of the lead frame in the emission direction may be equal to or less than twice a height of the resin dam, and a shortest distance between the trenches and the through-holes may be equal to or less than half the height of the resin dam.

According to this configuration, by placing the through-holes and the trenches near each other in relation to the height of the resin dam, it is possible to improve the mechanical strength between the lead frame and the resin dam near the end of the lead frame in the emission direction of the laser.

According to the present invention, it is possible to provide a laser device having high strength against mechanical stress.

### FURTHER INFORMATION ABOUT TECHNICAL BACKGROUND TO THIS APPLICATION

The disclosure of Japanese Patent Application No. 2009-230008 filed on Oct. 1, 2009 including specification, drawings and claims is incorporated herein by reference in its entirety.

### BRIEF DESCRIPTION OF THE DRAWINGS

These and other objects, advantages and features of the invention will become apparent from the following description thereof taken in conjunction with the accompanying drawings that illustrate a specific embodiment of the invention. In the Drawings:

FIG. 1A is a perspective view of a laser device according to an embodiment of the present invention;

FIG. 1B is a cut-out view showing an internal structure of the laser device shown in FIG. 1A;

FIG. 2A is a plan view of a laser device equipped with a laser element;

FIG. 2B is a cross-sectional view of the laser device along a line AA′ shown in FIG. 2A;

FIG. 2C is a lateral view of the laser device shown in FIG. 2A;

FIG. 3A is a cross-sectional view of trenches included in a laser device according to a first modification of the present invention;

FIG. 3B is a cross-sectional view of trenches included in a laser device according to the first modification of the present invention;

FIG. 4A plan view of a laser device according to a second modification of the present invention;

FIG. 4B is a lateral view of the laser device shown in FIG. 4A; and

FIG. 5 is a cut-out view showing an internal structure of a conventional laser device.

### DESCRIPTION OF THE PREFERRED EMBODIMENT(S)

Hereinafter, a laser device according to an embodiment of the present invention shall be described with reference to the Drawings. It is to be noted that although the present invention shall be described using the following embodiment and the attached Drawings, such description is for the purpose of exemplification and is not intended to limit the present invention thereto.

The laser device according to the present embodiment includes: a laser element; a plate-like lead frame which includes through-holes that penetrate a front plane and a back plane of the lead frame, the front plane being a surface on which the laser element is mounted such that an emission direction of a laser of the laser element is approximately parallel to the front plane; lead terminals provided at an end of the lead frame in a direction opposite to the emission direction; trenches provided on the front plane of the lead frame between an end of the lead frame in the emission direction and the through-holes; and a resin dam formed on the front plane of the lead frame using a resin so as to protrude in an area surrounding the laser element including positions of the through-holes, the resin dam having an open part in the emission direction, wherein the resin further fills the through-holes and the trenches, and bonds the lead frame and the resin dam by sealing together a part of each of the lead terminals and a part of the front plane and the back plane of the lead frame, in a vicinity of the lead terminals. According to this configuration, having trenches in the lead frame allows the resin which forms the resin dam to fill the trenches, thereby improving the mechanical strength between the lead frame and the resin dam near the end of the lead frame in the emission direction of the laser.

Hereinafter, a configuration of the laser device according to the embodiment of the present invention shall be described.

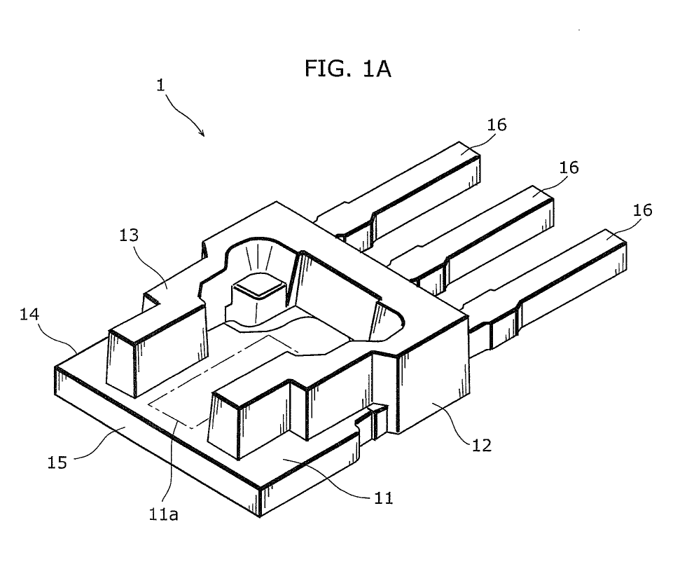

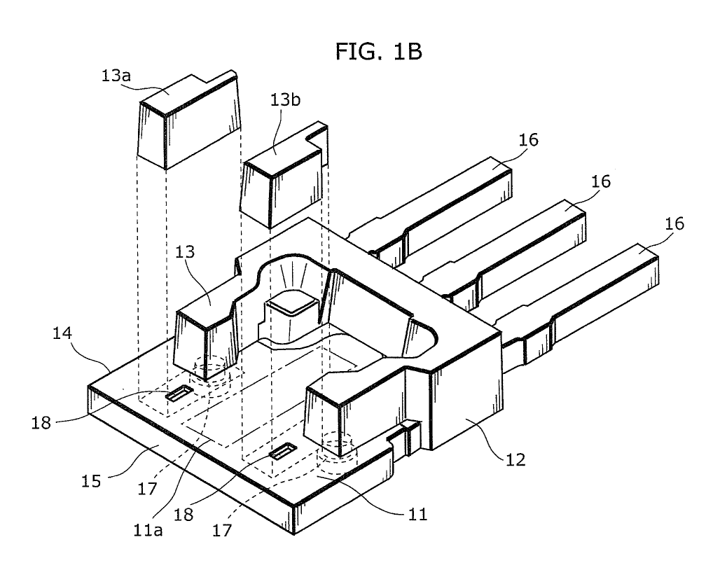

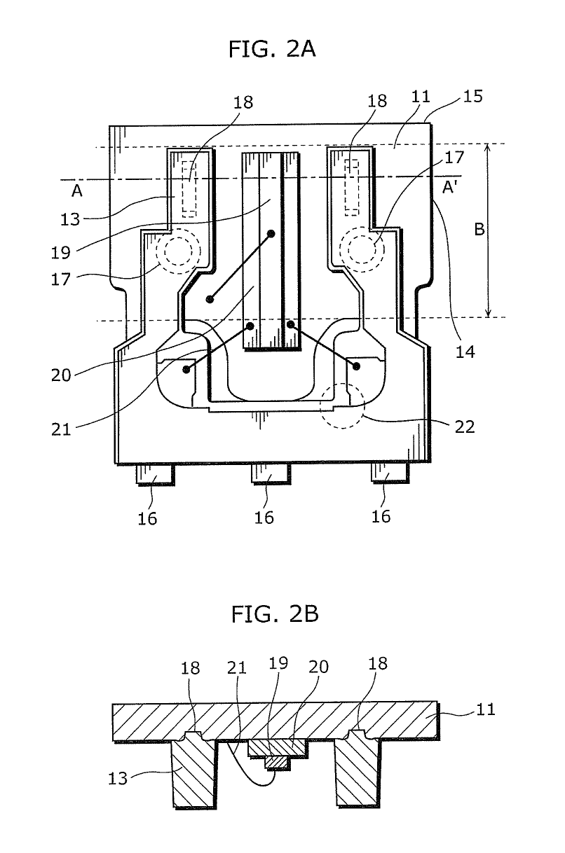

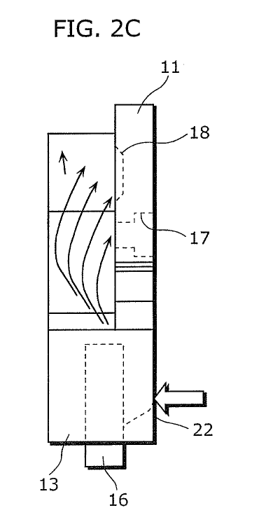

FIG. 1A is a perspective view of the laser device according to the embodiment of the present invention, and FIG. 1B is a cut-out view showing an internal structure of the laser device shown in FIG. 1A. Furthermore, FIG. 2A is a plan view for when a laser element is mounted on a front plane of the lead frame described earlier, FIG. 2B is a cross-sectional view of the laser device along a line AA′ shown in FIG. 2A, and FIG. 2C is a lateral view of the laser device in FIG. 2A as seen from the left. It is to be noted that in FIG. 1A and FIG. 1B, illustration of the laser element has been omitted. Furthermore, FIG. 2A shows a laser device 1 in such a way that the laser emission direction is the upward direction as seen from the side of laser element mounting plane.

As shown in FIG. 1A, the laser device 1 includes a plate-like lead frame 11, a resin dam 13 provided on the front plane of the lead frame 11, and lead terminals 16.

As shown in FIG. 1B, the lead frame 11 is configured of a plate material made from copper or a metal including copper. One end of the plate material has an X-reference plane 14 and another end which is orthogonal to the X-reference plane has a Y-reference plane. It is to be noted that the approximate center of the plate material is a laser element mounting part 11a at which a laser element 19 is mounted.

Furthermore, the resin dam 13 made from a resin is provided on the front plane of the lead frame 11 so as to surround the laser element mounting part 11a. The resin dam 13 is formed on the front plane of the lead frame 11 by way of a molding resin 12 so as to protrude in an area surrounding the laser element mounting part 11a, and is configured to have an open part in the laser emission direction.

Specifically, as shown in FIG. 1A, the resin dam 13 has a rough U-shape which surrounds the laser element in the three directions other than the laser emission direction, and the laser is emitted from the open part of the resin dam 13.

Furthermore, as shown in FIG. 1B, in the lead frame 11 under the resin dam 13 formed on both sides of the laser element mounting part 11a, two circular through-holes 17 are formed penetrating through the front plane and the back plane of the lead frame 11. In addition, in the front plane of the lead frame 11 under open-end parts 13a and 13b of the resin dam 13, two concave trenches 18 are formed each at an equidistant position from a corresponding one of the two through-holes 17. Furthermore, the molding resin 12 which forms the resin dam 13 fills the through-holes 17 and the trenches 18, and is integrally formed with the resin dam 13.

In addition, three of the lead terminals 16 are formed in the end of the lead frame 11 that is in the opposite direction to the laser emission direction, that is, the end that is in the direction opposite the open part of the resin dam 13 in the lead frame 11. Moreover, one part of the resin dam 13 located within the range indicated by the double arrow B in FIG. 2A is formed with the front plane of the lead frame 11 by filling resin into the through-holes (single-plane sealing), and the other part of the resin dam 13 covers the lead frame 11 up to the back plane (double-plane sealing), and thereby bonding the lead frame 11 and the resin dam 13. Furthermore, the resin dam 13 is formed so that its width decreases in the height direction from the lead frame 11, that is, downward from the lead frame 11 in FIG. 2B.

Furthermore, as shown in FIG. 2A, the laser element 19 is formed in the laser element mounting part 11a of the lead frame 11 surrounded by the resin dam 13, via a substrate called a sub-mount 20. Here, the laser element 19 is mounted so that the direction in which the resin dam 13 is open, that is, the upward direction in FIG. 2A is the laser emission direction. In addition, the laser element 19 is connected to the lead frame 11 through wires 21, and the sub-mount 20 is connected to the lead terminals 16 through the wires 21.

As shown in FIG. 2B and FIG. 2C, each of the trenches 18 is of a concave shape with a bottom plane, and the walls of the trenches 18 along the laser emission direction are sloped as shown in FIG. 2C. Each of the through holes 17 are formed so that the diameter at the front plane of the lead frame 11 is greater than the diameter at the back plane.

Furthermore, as shown in FIG. 2A, the lead frame 11 has gate opening 22 for injecting the molding resin 12. The molding resin 12 injected from the gate opening 22 flows in the direction of the arrow in FIG. 2C to form the resin dam 13 and fill the through holes 17 and the trenches 18. Furthermore, the molding resin 12 bonds the lead frame 11 and the resin dam 13 by sealing a part of the respective lead terminals 16, and a part of the front plane, back plane, and side planes of the lead frame 11, in the vicinity of the lead terminals 16.

Furthermore, as shown in FIG. 2A, the laser element 19, the sub-mount 20, the resin dam 13, the lead terminals 16, the through-holes 17, and the trenches 18 are provided axisymmetrically in the laser device 1, with the laser emission direction as the axis of symmetry.

Next, a method of manufacturing a laser device shall be described.

First, the (i) lead frame including the laser element mounting part 11a, the X-reference plane 14 and the Y-reference plane 15, and the through-holes 17 for improving adherence with the resin dam, and (ii) the lead terminals 16 are manufactured from a plate material made primarily from copper or a metal including copper. The respective center positions of the through-holes 17 are located further downward than the center position of the laser element 19 in FIG. 2A. Considering the size precision of the X-reference plane 14 and the Y-reference plane 15 when realized as a product, it is preferable that the respective center position of the through-holes 17 be located further downward than the bottom end of the laser element 19. The thickness of the lead frame 11 is normally between 0.3 to 0.4 mm inclusive, and its dimensions include an overall length of between 3 to 5 mm inclusive and an overall width of between 3.5 to 5.5 mm inclusive. Die forming, which is a press process using a mold tool, is a well-known fabrication method.

Next, the lead frame 11 is covered using the molding resin 12. Thermosetting epoxy resin, thermoplastic Liquid Crystal Polymer (LCP), and so on is normally widely used as the material for the molding resin 12. Although part of each of the lead terminals 16 is exposed from the molding resin 12 in order for the lead terminals 16 to be electrically conductive, the front and back planes of the lead frame 11 and a part of each of the lead terminals 16 are covered by the molding resin 12 so that the molding resin 12 and the lead frame 11 become an integrated body. Here, the laser element 19 mounting plane-side of the lead frame 11 is the front plane of the lead frame 11, and the plane opposite the laser element 19 mounting plane is the back plane. The molding resin 12 and the lead frame 11 are fastened by adopting a structure which wraps the molding resin around the lead frame 11.

Furthermore, at the same time, the resin dam 13 is formed in the periphery of the laser element mounting part 11a of the lead frame 11. Although the resin dam 13 refers to a part of the molding resin 12 which covers the lead frame 11, the term is used particularly in reference to the rough U-shaped part surrounding the laser element 19 in the three directions other than the laser emission direction as the resin dam 13. Furthermore, the resin dam 13 is single-plane sealed within the range indicated by the double arrow B in FIG. 2A, that is, the region other than the part that is wrapped around the lead frame 11 and the part filling the through holes 17, and is formed such that its width decreases particularly in the height direction, that is, its width decreases with the distance from the front plane of the lead frame 11. In the sealing process, a molding chase having the shape of the resin dam 13 is provided to the lead frame 11, the molding resin 12 which is heated and is in a molten liquid state flows in from a predetermined place in the molding chase indicated by the arrow in FIG. 2C and flows into all the corners of the inside of the molding chase that has been constructed in the predetermined size and shape of the resin dam 13. By filling the molding chase, the resin dam is formed and a part of the lead frame and the respective lead terminals 16 are covered, and thus the resin dam 13 and the lead frame 11 are bonded together as one, thereby completing the sealing process. It is to be noted that the place from which the molding resin 12 flows into the molding chase is normally called the gate opening 22. Since there are cases where the ability of the molding resin 12 to fill the molding chase changes due to the gate opening 22, the gate opening 22 is designed with care.

Next, a substrate called the sub-mount 20 is mounted in the laser element mounting part 11a of the lead frame 11. Ceramics such as aluminum nitride and the like are mainly as the material for the sub-mount 20. Mounting the laser element 19 directly to the laser element mounting part 11a of the lead frame 11 without using the sub-mount 20 places significant thermal stress on the laser element 19 since there is a significant difference between the coefficient of thermal expansion of the laser element 19 which is made from a semiconductor substrate and the coefficient of thermal expansion of the lead frame 11 which is made from metal, and thus brings about a problem with the reliability of the light-emitting characteristics of the laser element 19. By mounting the laser element 19 onto the lead frame 11 via the sub-mount 20, it is possible to maintain the reliability of the light-emitting characteristics of the laser element 19 and, in addition, prevent the misalignment of the mounting position of the laser element 19 even when there is a slight loss in the flatness of the laser element mounting part 11a. It is to be noted that the need for the flatness of the laser element mounting part 11a of the lead frame 11 is the same whether the sub-mount 20 is used or not.

Subsequently, the laser element 19 is mounted on the sub-mount 20. Here, the positional alignment between the laser element 19 and the lead frame 11 including the X-reference plane 14 and the Y-reference plane 15 is performed precisely. This is done so that, after the laser device is equipped in a product (not illustrated), the position of the luminous point of the laser element 19 accurately matches the position required in the equipped device. The X-reference plane 14 and the Y-reference plane 15 are provided for the alignment with a hole (not illustrated) of the product to which the laser device is to be fitted.

Next, after mounting the laser element 19, the laser element 19 and the sub-mount 20, and the lead frame 11 and the lead terminals 16, are connected by wires 21 made from metal so that each becomes electrically conductive.

Thus, the laser device 1 is completed in this manner.

In the laser device 1 manufactured in the above-described manner, the trenches 18 are formed in the lead frame 11 in the press process during the forming of the lead frame 11. The trenches 18 are formed in a portion of the lead frame 11 that is single-plane sealed and further upward than the through-holes 17 in FIG. 2A. This is roughly the portion of the lead frame 11 that is further upward than the through holes 17 shown in FIG. 2A. Forming the trenches 18 improves the mechanical strength against external force during pinching by tweezers and the like, of the open-end parts 13a and 13b of the resin dam 13 that are positioned further upward than the through holes 17. The single-plane sealed part of the resin dam 13 which is prone to detaching can be made less prone to detaching through the forming of the trenches 18. Although, in the handling using tweezers and the like, picking up is normally performed by pinching both sides of the lead frame 11, even when the open-end parts 13a and 13b of the resin dam 13 are pinched by mistake, the probability of producing a reject is significantly reduced.

Furthermore, as shown in FIG. 2A, the portion in which the trenches 18 are to be provided is at a side of FIG. 2A that is further upward than the through-holes 17. Adopting such a position makes it possible to further add the bonding force brought about by the trenches 18 to the state in which the resin dam 13 and the lead frame 11 are made into an integrated body primarily by way of the through-holes 17, and thus it is possible to make the single-plane sealed resin dam 13 less prone to deformation.

Furthermore, each of the trenches 18 has an elongated shape that is approximately parallel to the laser emission direction of the laser element 19. In other words, the trenches 18 are formed elongated in the vertical direction of FIG. 2A. As described above, the molding resin 12 in the sealing process is heated and injected in a liquid state into the molding chase. The liquid molding resin 12 comes into contact with the mold while flowing into it, thereby cooling down and hardening to become the resin dam 13. A void (air pocket) is created when the flow of the liquid molding resin 12 is inhibited in some way. When a void is created, there is a possibility for the void to expand due to heat, which leads to product destruction originating from the void, thus making the product defective. Alternatively, since there is no close-adhesion in the part where the void is created, detachment occurs starting from the void when mechanical stress is applied. Consequently, as described above, the trenches 18 are formed elongated in the vertical direction of FIG. 2A so as not to inhibit the flow of the molding resin 12 that is in a liquid state during the sealing process. Therefore, the creation of a void due to the trenches 18 can be suppressed. Furthermore, since the resin dam 13 within the range indicated by the double arrow B in FIG. 2A has a structure which is narrow and elongated in the vertical direction of FIG. 2A, forming the trenches 18 to be elongated along the direction of the resin dam 13 within the range indicated by the double arrow B in FIG. 2A increases the advantageous effect of improving the mechanical strength of the open-end parts 13a and 13b of the resin dam 13, more than when the trenches 18 are formed to be elongated in the horizontal direction of FIG. 2A.

Here, describing the elongated shape of the trenches 18 in detail, the size of the trenches 18 is measured in the length direction of the trenches 18 along the direction of the resin dam 13 and the width direction perpendicular to the length direction, and it is sufficient that the measurement of the trenches 18 in the length direction is longer. Therefore, a shape in which the measurement in the length direction and the width direction are equal, such as a square or a true circle, is not desirable and it is preferable to adopt a shape which follows the resin dam 13 as described above.

Furthermore, in order to reduce the impact of the forming of the trenches 18 on the lead frame 11, the trenches 18 should be provided axisymmetrically on both sides of the laser element 19, with the laser emission direction of the laser device 1 as the axis of symmetry. As previously described, the X-reference plane 14 and the Y-reference plane 15 are provided in the lead frame 11, and such reference planes are reference planes used for positioning the laser device with a product. Providing a trench 18 on only one side of the laser element 19 would upset the position of the reference planes, and thus it is preferable that the trenches 18 be provided symmetrically on both sides of the laser element 19. This applies not only to the trenches 18 but also to the through-holes 17, and thus it is preferable that the through-holes 17 also be provided symmetrically on both sides of the laser element 19.

Furthermore, with regard to the depth of the trenches 18, the aim here is to prevent the part of the resin dam 13 which is further upward than the through-holes 17 in FIG. 2A, that is, the part near the open-end parts 13a and 13b, from detaching from the lead frame 11, side slipping and getting deformed. Therefore, as long as such aim is achieved, lesser depth for the trenches 18 allows for lesser deformation of the lead frame 11 and reduced danger from residual stress. According to our studies, the advantageous effect is produced starting when the depth of the trenches 18 is approximately 15 μm. In addition, it has been confirmed that, when the depth of the trenches 18 is equal to or less than half the thickness of the lead frame 11, the deformation of the lead frame 11 itself can suppress the impact on the reliability or precision of the laser device 1.

Furthermore, when the distance between the through-holes 17 and the trenches 18 is great, the open-end parts 13a and 13b of the resin dam 13 become prone to popping up, strength-wise, and thus the open-end parts 13a and 13b of the resin dam 13 detach from the formed trenches 18 and become deformed. Furthermore, when the height of the resin dam 13 is low, the open-end parts 13a and 13b easily pop up from the lead frame 11. Therefore, specifically, with regard to the height of the resin dam 13, the length of the resin dam 13 upward of the through-holes 17, and the distance between the through-holes 17 and the trenches 19, the preferred implementation is one in which, in the front plane of the lead frame 11, the shortest distance between the through-holes 17 and the end plane of the resin dam 13 near the end of the lead frame 11 in the laser emission direction of the laser element 19 (that is, the Y-reference plane 15 of the lead frame 11) is equal to or less than twice the height of the resin dam 13, and the shortest distance between the trenches 18 and the through-holes 17 is equal to or less than half the height of the resin dam 13.

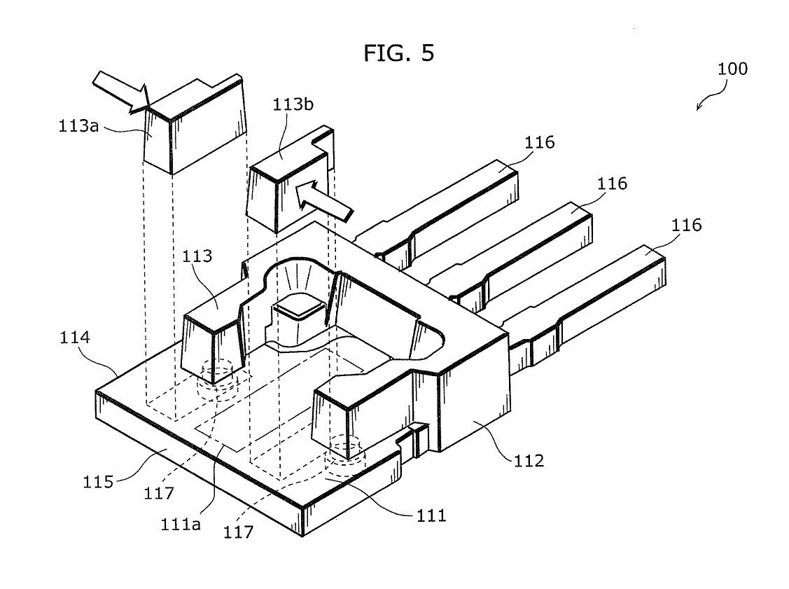

It is to be noted that according to the above-described configuration of the laser device 1, it has been confirmed that the laser device 1 is 1.5 to 2 times stronger than conventional in terms of the mechanical strength in the case where the open-end parts 13a and 13b of the resin dam 13 of the laser device 1 shown in FIG. 1B are pinched from the outside in the same manner as the conventional example shown in FIG. 5. Therefore, the mechanical strength of the laser device 1 is significantly improved. Furthermore, aside from this, the reliability and the positional accuracy of the laser element 19 are comparable to those of the conventional structure.

(First Modification)

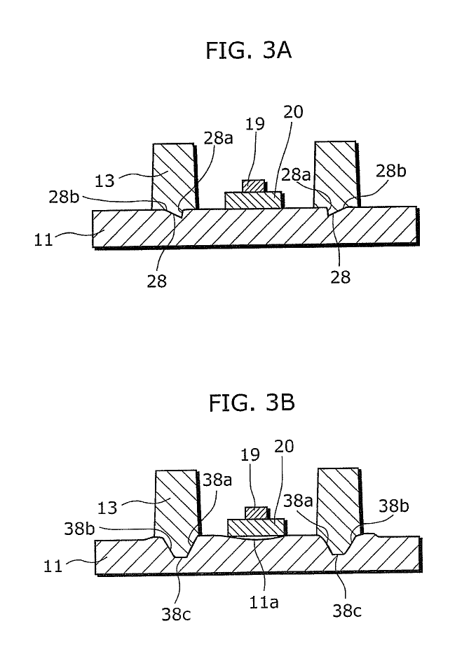

Next, a first modification of the embodiment of the present invention shall be described. FIG. 3A and FIG. 3B are diagrams each showing a configuration of a laser device in this first modification.

The point of difference between the laser device shown in FIG. 3A and FIG. 3B and the laser device 1 shown in FIG. 2B is that the trenches formed in the lead frame 11 are formed in such a way that each of a first wall closer to the laser element mounting part 11a onto which the laser element 19 is to be mounted and a second wall farther from the laser element have a predetermined slope.

Since the laser element mounting part 11a of the lead frame 11 is the portion onto which the laser element 19 is to be mounted, the laser element mounting part 11a needs to be flatter than a chip mounting part (what is called a die pad) of a package using a lead frame, such as a Quad Flat Package (QFP). When the flatness of the laser element mounting part 11a is impaired, there is a possibility that the heat generated from the laser element 19 will not be properly conveyed to the lead frame 11, and the temperature of the laser element will rise, and its reliability will be impaired. In addition, due to a deterioration in the precision of the height of the laser element 19, the positional accuracy of the emitted laser deteriorates.

As previously described, the forming of the trenches 18 of the lead frame 11 is normally performed using a press process using a mold tool. However, since the press process presses the mold tool onto the lead frame to attain the predetermined shape, when the trenches 18 are formed, the material of the lead frame 11 corresponding to the trenches (the metal material displaced in the press process for forming the trenches using the mold tool) bulges around the trenches 18. When there is a bulge of material in the laser element mounting part 11a, the laser element 19 to be mounted onto the material is mounted at an angle, or a gap is formed between the lead frame and the laser element or sub-mount. The laser emitted from the laser element 19 which has been mounted at an angle does not follow the predetermined direction, and thus the function of the laser device cannot be achieved. Furthermore, when a gap is formed between the lead frame and laser element or the sub-mount, satisfactory heat conduction characteristics cannot be obtained. As such, when the trenches 18 are formed, the laser element 19 is mounted at a position which is sufficiently distant from the trenches 18 so as to be flat, and thus miniaturization of the laser device 1 becomes difficult.

Consequently, as with trenches 28 shown in FIG. 3A, each of the trenches 28 is formed in such a way that a first wall 28a closer to the laser element mounting part 11a has an approximately-vertical precipitous shape, and a second wall 28b farther from the laser element mounting part 11a has a gentler slope than the first wall 28a.

In this manner, by providing slopes to the first wall 28a and the second wall 28b of the trenches 28, the material of the lead frame 11 is displaced away from the laser element mounting part 11a. Therefore, by forming such trenches 28, the flatness of the laser element mounting part 11a is not impaired, heat conduction characteristics are not impaired, and misalignment of the laser emission direction can be suppressed.

It is to be noted that, as with trenches 38 shown in FIG. 3B, even when each of the trenches 38 has a bottom plane 38c, it is sill possible to suppress the bulging of material to some extent, by sloping a first wall 38 which is closer to the laser element mounting part 11a and a second wall 38b which is farther from the laser element mounting part 11a. Specifically, each of the trenches 38 should be formed in such a way that the first wall 38a closer to the laser element mounting part 11a has an approximately-vertical precipitous shape, and the second wall 38b farther from the laser element mounting part 11a has a gentler slope than the first wall 38a.

When checking the cross-section of the trenches 38 respectively located on opposite sides of the laser element 19, for each of the trenches 28, most of the material is displaced on the side opposite to the laser element mounting part 11a and flatness is more or less maintained in the laser element mounting part 11a-side, as shown in FIG. 3B. Furthermore, strictly speaking, providing slopes does not mean that absolutely no material will be displaced toward the laser element mounting part 11a. However, by forming the trenches 38 to have slopes in this manner so as to maintain the flatness of the laser element mounting part 11a as much as possible and reduce the distance between the trenches 38 and the laser element 19, miniaturization of the laser device 1 becomes possible.

### (Second Modification)

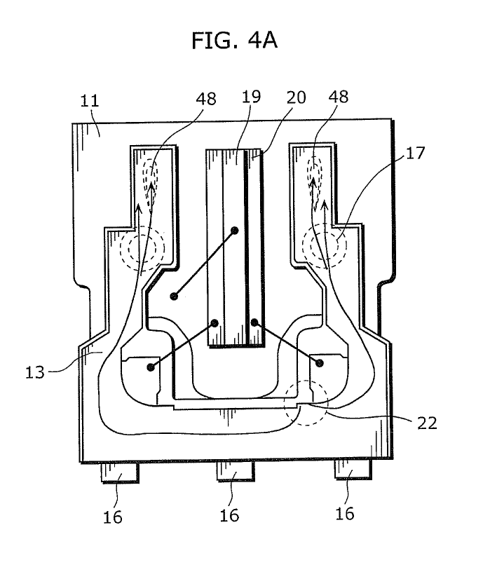

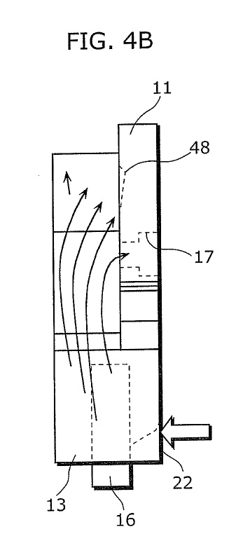

Next, a second modification of the embodiment of the present invention shall be described. FIG. 4A and FIG. 4B are diagrams each showing a configuration of a laser device in the second modification.

The point of difference between the laser device shown in FIG. 4A and FIG. 4B and the laser device 1 shown in FIG. 2A and FIG. 2C is that the shape of each of trenches 48 formed in the lead frame 11 is formed to have a greater width and depth toward the end of the lead frame 11 in the laser emission direction.

Considering the flow of the molding resin 12 which flows into the trenches 18 when the resin dam 13 is formed, it is preferable that the trenches 48 have greater width towards the end of the lead frame 11 in the laser emission direction (that is the Y-reference plane 15 of the lead frame 11), as shown in FIG. 4A. Here, what is meant by the width of the trenches 48 increasing toward the laser emission direction is that, when comparing the width of the respective trenches 48 at the part where the flow of the molding resin 12 starts and the width at the part where the flow of the molding resin 12 ends at the time when the molding resin 12 flows into the trenches 48 from the gate opening 22, the width at the end of the flow of the molding resin 12 is greater.

In FIG. 4A, in the sealing process for forming the resin dam 13, the molding resin 12 flowing from the gate opening 22 flows in the upward direction of FIG. 4A, that is, the laser emission direction, as shown by the arrows in FIG. 4A. Therefore, comparing the width in the downward direction and the width in the upward direction of the trenches 48 in the present modification, the trenches 48 are formed with a width that increases in the upward direction. Furthermore, with respect to the depth of the trenches 48, it is preferable that the trenches 48 be formed with a depth that increases towards the end of the lead frame 11 in the laser emission direction of the laser element 19 (that is, towards the Y-reference frame 15 of the lead frame 11). Specifically, when comparing the depth of the respective trenches 48 at the part where the molding resin 12 starts to flow in and the depth at the part where the flow of the molding resin 12 ends, it is preferable that the depth of the part at the end of the flow of the molding resin 12 be made greater, as shown in FIG. 4B.

By adopting such a configuration, it is possible to facilitate the flowing of the molding resin 12 into the trenches 48, eliminate voids of the molding resin 12, and reduce the risk of mechanical strength deterioration.

It should be noted that the present invention is not limited to the above-described embodiment and modifications, and various improvements and modifications may be carried out within the scope of the essence of the present invention.

For example, the size and shape of the lead frame, resin dam, through-holes, and trenches are not limited to the above described sizes and shapes, and may be changed as appropriate.

Furthermore, the material of the lead frame is not limited to copper, and the lead frame may be of a material that includes copper, or it may be made from another metal.

Furthermore, the material of the sub-mount 20 is not limited to aluminum nitride, and may also be other ceramics. Furthermore, a material other than ceramic may also be used.

Furthermore, the material of the molding resin is not limited to an epoxy resin, thermoplastic Liquid Crystal Polymer (LCP), and may be another material such as polyimide and so on. Furthermore, the molding resin is not limited to a thermosetting resin, and other types, such as photo-curable resins may also be used.

Although only an exemplary embodiment of this invention has been described in detail above, those skilled in the art will readily appreciate that many modifications are possible in the exemplary embodiment without materially departing from the novel teachings and advantages of this invention. Accordingly, all such modifications are intended to be included within the scope of this invention.

### INDUSTRIAL APPLICABILITY

The present invention is useful as a semiconductor laser device used in writing, erasing, and reading of information to and from an optical disc such as a DVD.

What is claimed is:

1. A laser device, comprising:
a laser element;
a plate-like lead frame which includes through-holes that penetrate a front plane and a back plane of said lead frame, the front plane being a surface on which said laser element is mounted such that an emission direction of a laser of said laser element is approximately parallel to the front plane;
lead terminals provided at an end of said lead frame in a direction opposite to the emission direction;
trenches provided on the front plane of said lead frame between an end of said lead frame in the emission direction and said through-holes; and
a resin dam formed on the front plane of said lead frame using a resin so as to protrude in an area surrounding said laser element including positions of said through-holes, said resin dam having an open part in the emission direction,
wherein the resin further fills said through-holes and said trenches, and bonds said lead frame and said resin dam by sealing together a part of each of said lead terminals and a part of the front plane and the back plane of said lead frame, in a vicinity of the lead terminals.

2. The laser device according to claim 1,
wherein each of said trenches has a shape that is elongated in a direction approximately parallel to the emission direction.

3. The laser device according to claim 1,
wherein each of said trenches is formed with a width that increases towards the end of said lead frame in the emission direction.

4. The laser device according to claim 1,
wherein each of said trenches is formed with a depth that increases towards the end of said lead frame in the emission direction.

5. The laser device according to claim 2,
wherein, in each of said trenches, a first wall closer to a mounting position of said laser element has an approximately-vertical precipitous slope, and a second wall farther from the mounting position of said laser element has a gentler slope than the first wall.

6. The laser device according to claim 1,
wherein said trenches are formed axisymmetrically with the emission direction as an axis of symmetry.

7. The laser device according to claim 1,
wherein a depth of said trenches is 15 μm or more and is equal to or less than half a thickness of said lead frame.

8. The laser device according to claim 1,
wherein, in the front plane of said lead frame, a shortest distance between said through-holes and an end plane of said resin dam near the end of said lead frame in the emission direction is equal to or less than twice a height of said resin dam, and a shortest distance between said trenches and said through-holes is equal to or less than half the height of said resin dam.
